(19) United States
(12) Patent Application Publication
(10) Pub. No.: US 2014/0220717 A1
(43) Pub. Date: Aug. 7, 2014

(54) METHOD FOR MANUFACTURING LIGHT EMITTING DIODE PACKAGE

(71) Applicant: ADVANCED OPTOELECTRONIC TECHNOLOGY, INC., Hsinchu Hsien (TW)

(72) Inventors: HOU-TE LIN, Hsinchu (TW); PIN-CHUAN CHEN, Hsinchu (TW); LUNG-HSIN CHEN, Hsinchu (TW)

(73) Assignee: ADVANCED OPTOELECTRONIC TECHNOLOGY, INC., Hsinchu Hsien (TW)

(21) Appl. No.: 14/162,754

(22) Filed: Jan. 24, 2014

(30) Foreign Application Priority Data
Feb. 4, 2013 (CN) 201310042625X

(51) Int. Cl. H01L 33/52; H01L 33/60

(52) U.S. Cl. CPC H01L 33/52; H01L 33/60
USPC 438/27

(57) ABSTRACT

A method for manufacturing an LED package includes the steps: providing a lead frame including many pairs of first and second electrodes, the first electrodes and second electrodes each including a main body, an extension electrode, and a supporting branch, the first electrodes in a column and the second electrodes in a column being linearly connected by a first and second tie bars, respectively; forming many molded bodies to correspond to the pairs of the first and second electrodes, the first and second main bodies being embedded into the molded bodies, the first and second extension electrodes being exposed out from a periphery of the molded body, bottoms of the first and second supporting branches being exposed at a bottom of the molded body; disposing LED dies in corresponding receiving cavities; and cutting the first and second tie bars and the molded bodies and the lead frame.

### TECHNICAL FIELD

The present disclosure relates to a method for manufacturing light emitting diode (LED) packages, and particularly to a method for manufacturing LED packages each having a pair of first and second electrodes embedded into a reflecting cup.

### DESCRIPTION OF RELATED ART

LEDs are solid state light emitting devices formed of semiconductors, which are more stable and reliable than other conventional light sources such as incandescent bulbs. Thus, LEDs are widely used in various fields such as numeral/character displaying elements, signal lights, light sources for lighting and display devices.

A typical method for manufacturing an LED package usually includes the following steps: providing a substrate with electrical structures (i.e., electrodes) formed thereon; forming a reflecting cup on the top of the substrate, the reflecting cup defining a receiving cavity therein; disposing an LED die in the receiving cavity of the reflecting cup and electrically connecting the LED die to the electrical structures exposed at the bottom of the receiving cavity via gold wires; and forming an encapsulant layer in the receiving cavity to encapsulate the LED die. However, the LED package manufactured by the method has low bonding force between the substrate and the reflecting cup, the substrate and the electrical structures are easily to separate from the reflecting cup, resulting in a poor sealing performance.

What is needed, therefore, is a method for manufacturing light emitting diode package which can overcome the above-mentioned limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is a flow chart of a method for manufacturing a light emitting diode package in accordance with an exemplary embodiment of the present disclosure.

FIGS. 2 is a top plan view of a lead frame of the light emitting diode package obtained by a first step of the method shown in FIG. 1.

FIG. 3 is an enlarged view of part III of the lead frame of FIG. 2, and shows a pair of electrodes thereof, together with two tie bars respectively located at opposite outer ends of the pair of electrodes.

FIG. 4 is a cross-sectional view of the pair of electrodes of FIG. 3, taken along line IV-IV thereof.

FIG. 5 is a cross-sectional view of the pair of electrodes of FIG. 3, taken along line V-V thereof.

FIG. 6 is similar to FIG. 3, but viewed from an inverted aspect.

FIG. 7 is a schematic, cross-sectional view of a part of the lead frame of FIG. 2, together with a mold for accommodating the part of the lead frame, wherein only a pair of electrodes of the lead frame is shown.

FIG. 8 is similar to FIG. 7, but viewed from a bottom of the part of the lead frame shown in FIG. 7, wherein a female mold of the mold is removed for clarity.

FIG. 9 is a top plan view of light emitting diode element of the light emitting diode package obtained by a second step of the method shown in FIG. 1.

FIG. 10 is an enlarged view of part X of the light emitting diode element of FIG. 9.

FIG. 11 is a cross-sectional view of the light emitting diode element of FIG. 10, taken along line XI-XI thereof.

FIG. 12 is similar to FIG. 10, but viewed from an inverted aspect.

FIG. 13 is a top view of the light emitting diode package manufactured by the method of FIG. 1 of the present disclosure.

FIG. 14 is a cross-sectional view of the light emitting diode package of FIG. 13, taken along line XIV-XIV thereof.

FIG. 15 is similar to FIG. 13, but viewed from an inverted aspect.

### DETAILED DESCRIPTION

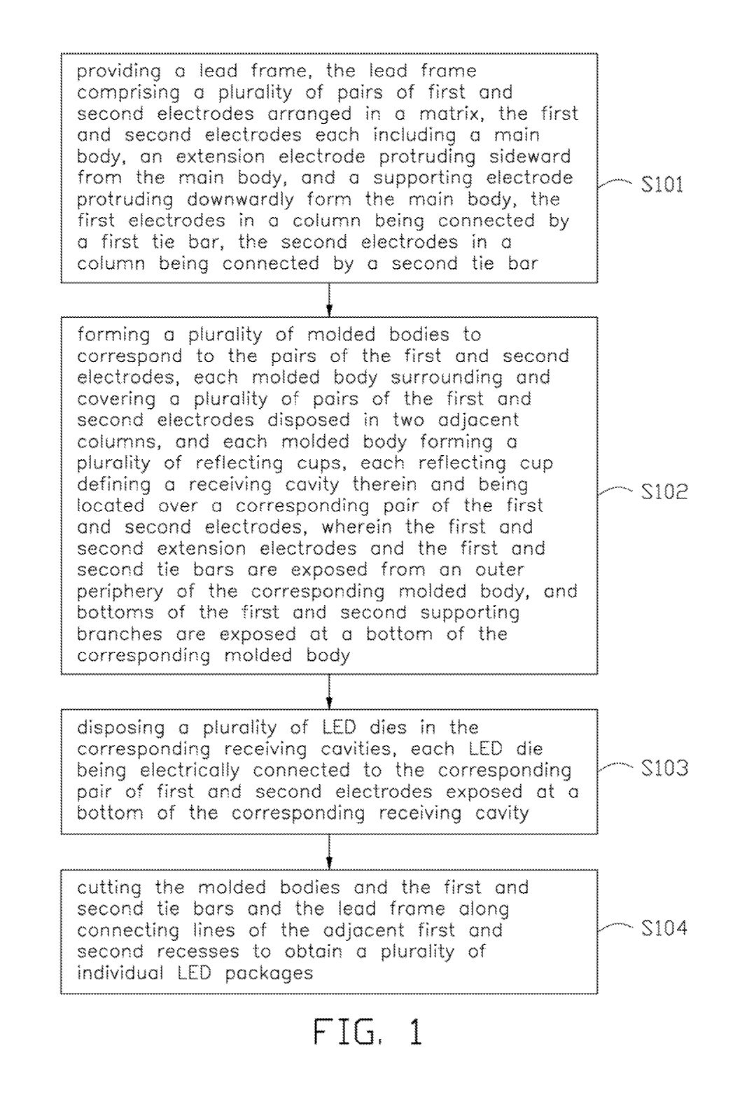

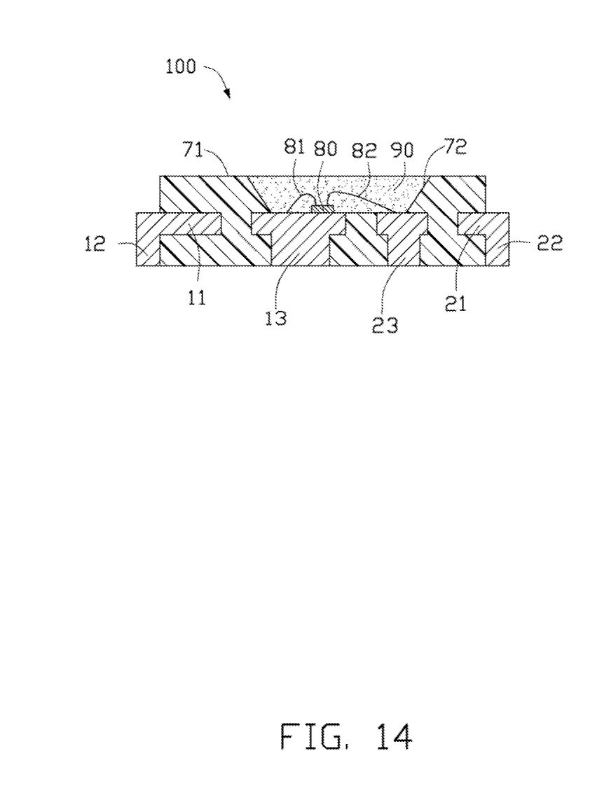

Referring to FIG. 1, a method for manufacturing a light emitting diode (LED) package 100 (see FIG. 14) in accordance with an exemplary embodiment of the present disclosure is shown. The method includes the following steps:

In step S101 (also referring to FIG. 1), a lead frame 50 is provided, and the lead frame 50 includes a plurality of pairs of electrodes arranged in a matrix. Each pair of electrodes includes a first electrode 10 and a second electrode 20 adjacent to the first electrode 10. The first electrodes 10 arranged in a column are connected together by a first connecting bar 30, and the second electrodes 20 arranged in a column are connected together by a second connecting bar 31.

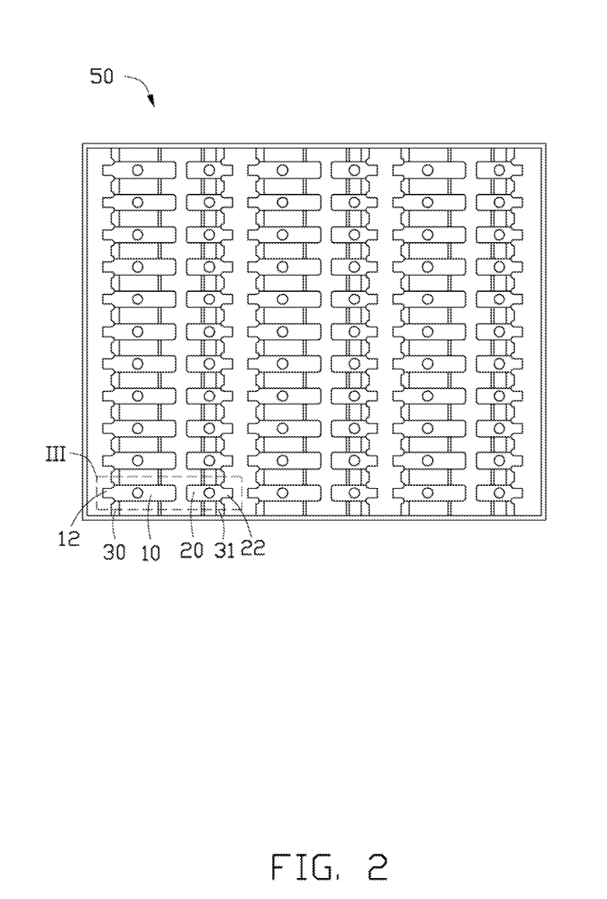

The lead frame 50 further includes a plurality of metal wires (not labeled) firmly connected between two opposite sides (i.e., the top side and the bottom side) thereof. The first and second electrodes 10, 20 are fixed to the lead frame 50 by the metal wires. In the present embodiment, there are three columns of first electrodes 10 and three columns of second electrodes 20. The three columns of first electrodes 10 and the three columns of second electrodes 20 are arranged alternately along a predetermined direction (i.e., the left-to-right direction as viewed from FIG. 2) of the lead frame 50.

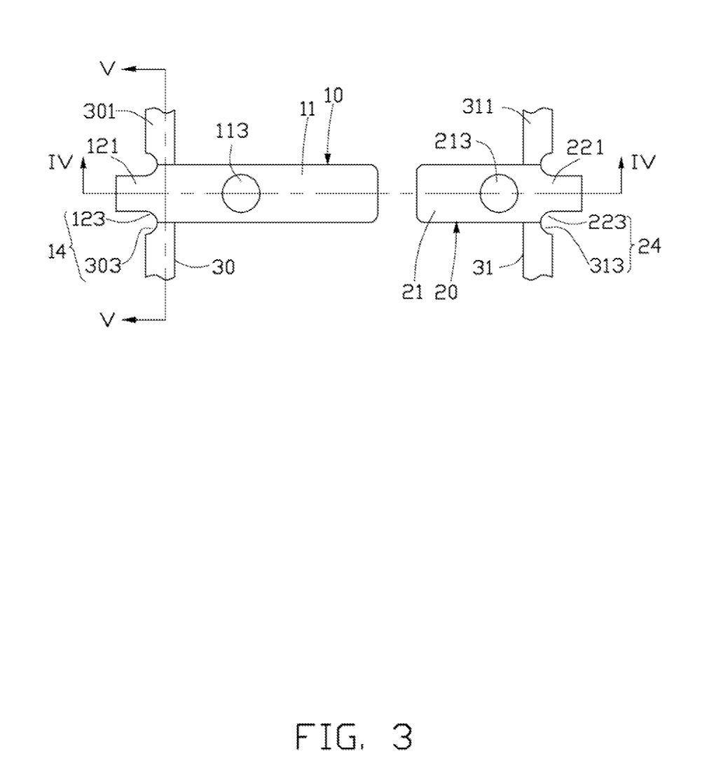

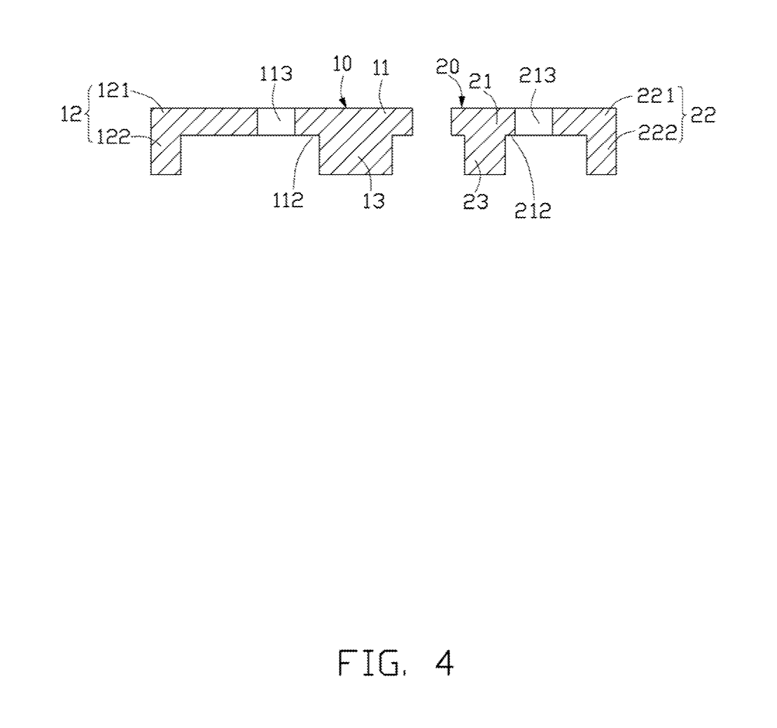

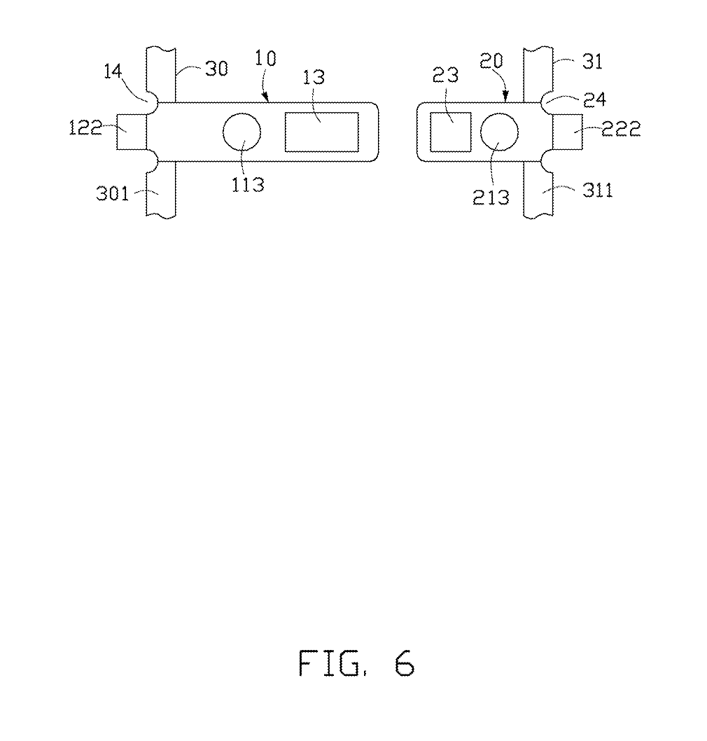

Referring also to FIGS. 3-6, because the plurality of pairs of electrodes, i.e., the first and second electrodes 10, 20, have the same structure, this description and the accompanying drawings mainly illustrate one pair of the first and second electrodes 10, 20. The first electrode 10 includes an elongated first main body 11, a first extension electrode 12 protruding laterally from a left end of the first main body 11 and remote from the second electrode 20 which is in the same pair with the first electrode 10, and a first supporting branch 13 protruding downwardly from a bottom 112 of the first main body 11 and adjacent to the second electrode 20 which is in the same pair with the first electrode 10. The second electrode 20 includes an elongated second main body 21, a second extension electrode 22 protruding laterally from a right end of the second main body 21 and remote from the first electrode 10 which is in the same pair with the second electrode 20, and a second supporting branch 23 protruding downwardly from a bottom 212 of the second main body 21 and adjacent to the first electrode 10 which is in the same pair with the second electrode 20. The first main body 11 and the second main body 21 are arranged, as depict, in a line extending along the left-to-right direction as shown in FIG. 3. Widths of the first and second extension electrodes 12, 22 are smaller than that of the first and second main bodies 11, 21, respectively.

The first and second extension electrodes 12, 22 each have an inverted L-shaped configuration. The first extension electrode 12 includes a first connecting portion 121 extending horizontally outward from the left end of the first main body 11, and a first extension portion 122 extending downwardly from a left end of the first connecting portion 121 and substantially perpendicular to the first connecting portion 121. The second extension electrode 22 includes a second connecting portion 221 extending horizontally outwardly from the right end of the second main body 21, and a second extension portion 222 extending downwardly from a right end of the second connecting portion 221 and substantially perpendicular to the second connecting portion 221. Tops of the first and second extension electrodes 12, 22 are coplanar with tops of the first and second main bodies 11, 21. Bottoms of the first and second extension electrodes 12, 22 are coplanar with bottoms of the first and second supporting branches 13, 23.

The first tie bar 30 includes a plurality of first connecting sections 301 spaced from each other. The second tie bar 31 includes a plurality of spaced second connecting sections 311. Each first connecting section 301 extends between two adjacent first electrodes 10 in a column, and each second connecting section 311 extends between two adjacent second electrodes 20 in a column. The first connecting section 301 is adjacent to the first extension electrode 12, and the second connecting section 311 is adjacent to the second extension electrode 22.

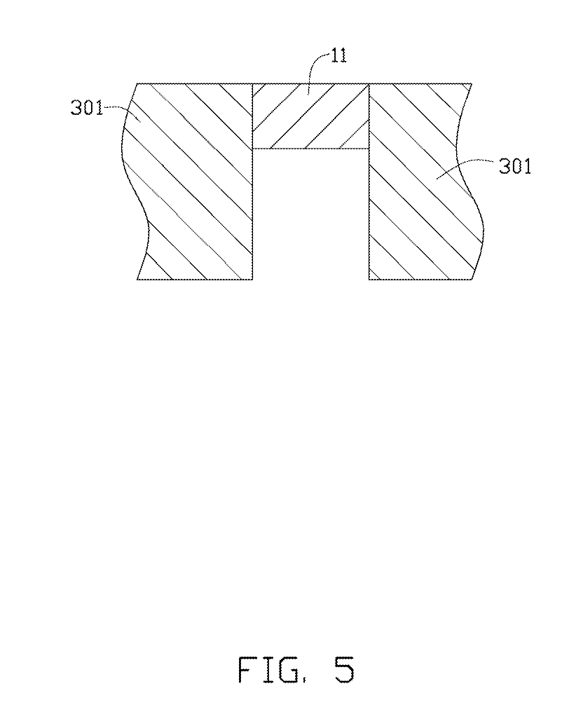

The first extension electrode 12 has two first cutouts 123 at opposite sides of the first connecting portion 121 thereof, and the second extension electrode 22 has two second cutouts 223 at opposite sides of the second connecting portion 221 thereof. The first connecting section 301 has two spaced third cutouts 303 (only one third cutout 303 shown in FIG. 3) formed at two ends thereof, and the second connecting section 311 has two spaced fourth cutouts 313 (only one fourth cutout 313 shown in FIG. 3) formed at two ends thereof. The first cutout 123 and the adjacent third cutout 303 cooperatively define a first recess 14. The second cutout 223 and the adjacent fourth cutout 313 cooperatively define a second recess 24. The first recess 14 is located at a joint where the first electrode 10 meets the first connecting section 301 of the first tie bar 30. The second recess 24 is located at a joint where the second electrode 20 meets the second connecting section 311 of the second tie bar 31. Tops of the first and second connecting sections 301, 311 are coplanar with the tops of the first and second main bodies 11, 21 (see FIG. 5). Bottoms of the first and second connecting sections 301, 311 are coplanar with bottoms of the first and second extension electrodes 12, 22 and bottoms of the first and second supporting branches 13, 23.

The first and second supporting branches 13, 23 are square cylindrical. A width of the first supporting branch 13 is smaller than that of the first main body 11, and a width of the second supporting branch 23 is smaller than that of the second main body 21. The first supporting branch 13 is near the right end of the first main body 11 and adjacent to the second electrode 20, and the second supporting branch 23 is near the left end of the second main body 21 and adjacent to the first electrode 10.

The first electrode 10 further defines a first through hole 113 extending through the first main body 11 thereof. The first through hole 113 is located between the first extension electrode 12 and the first supporting branch 13. The second electrode 20 further defines a second through hole 213 extending through the second main body 21 thereof. The second through hole 213 is located between the second extension electrode 22 and the second supporting branch 23.

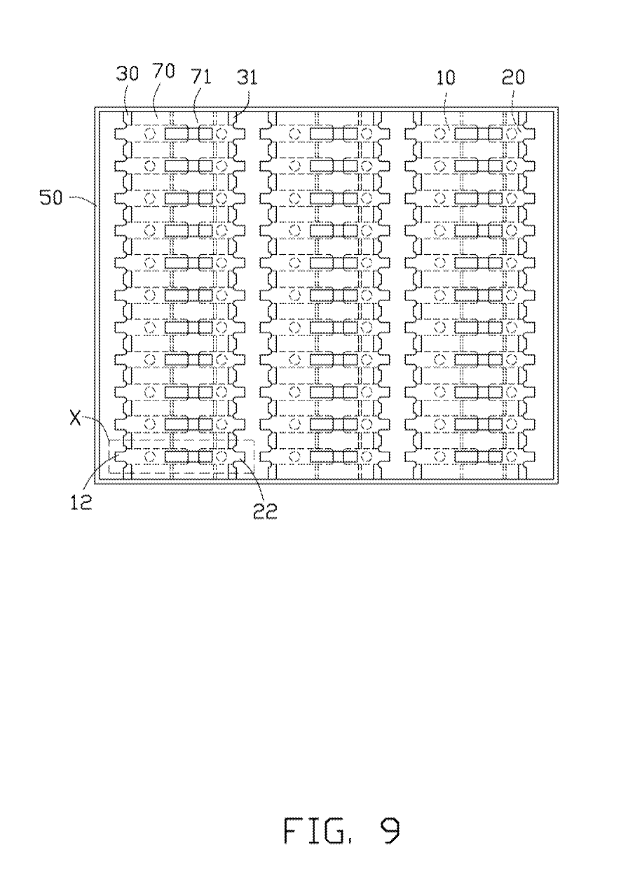

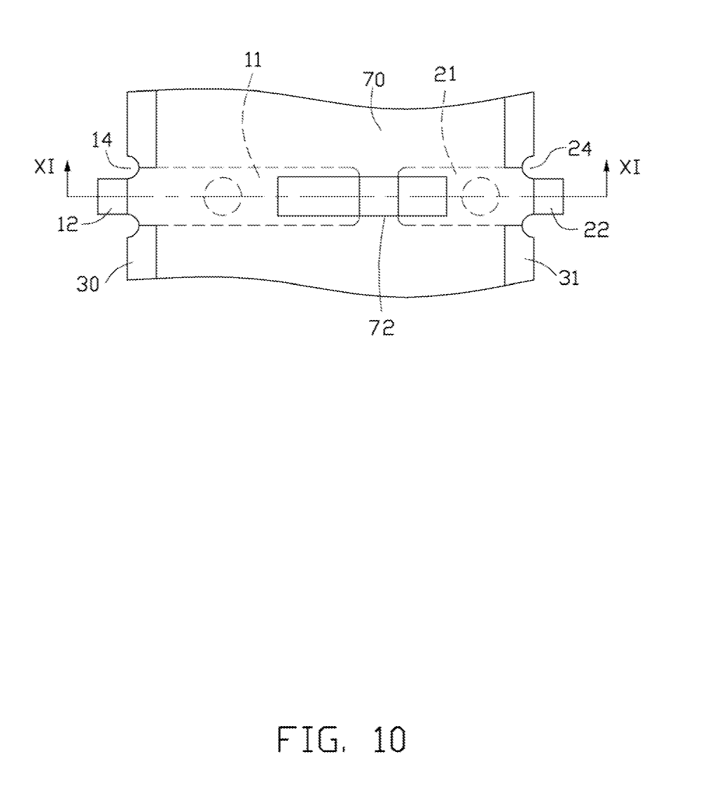

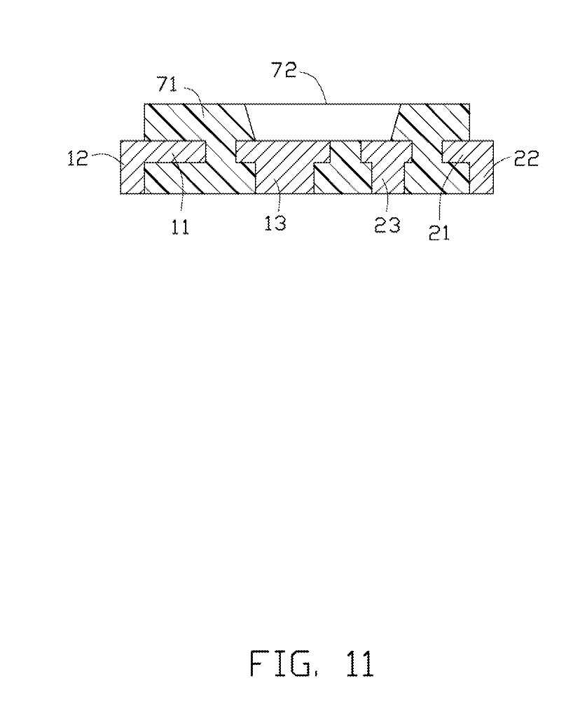

In step S102 (also referring to FIGS. 9-12), a plurality of molded bodies 70 is formed to correspond to the pairs of the first and second electrodes 10, 20. Each molded body 70 surrounds and covers a plurality of pairs of the first and second electrodes 10, 20 disposed in two adjacent columns. Each molded body 70 forms a plurality of reflecting cups 71. Each reflecting cup 71 defines a receiving cavity 72 therein, and the receiving cavity 72 is located above a corresponding pair of the first and second electrodes 10, 20. The first and second extension electrodes 12, 22, together with the first and second tie bars 30, 31, are exposed from a periphery of the corresponding molded body 70. Bottoms of the first and second supporting branches 13, 23 are exposed at a bottom of the corresponding molded body 70.

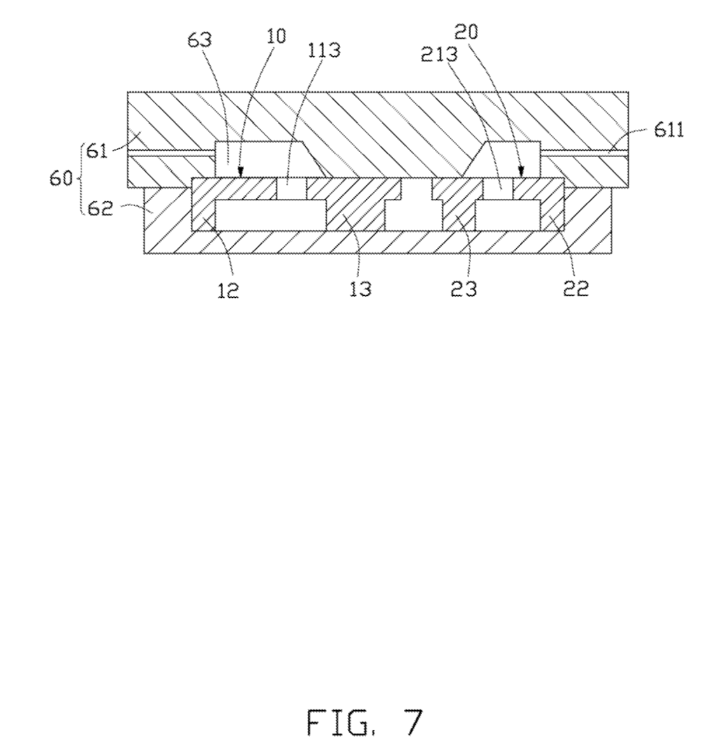

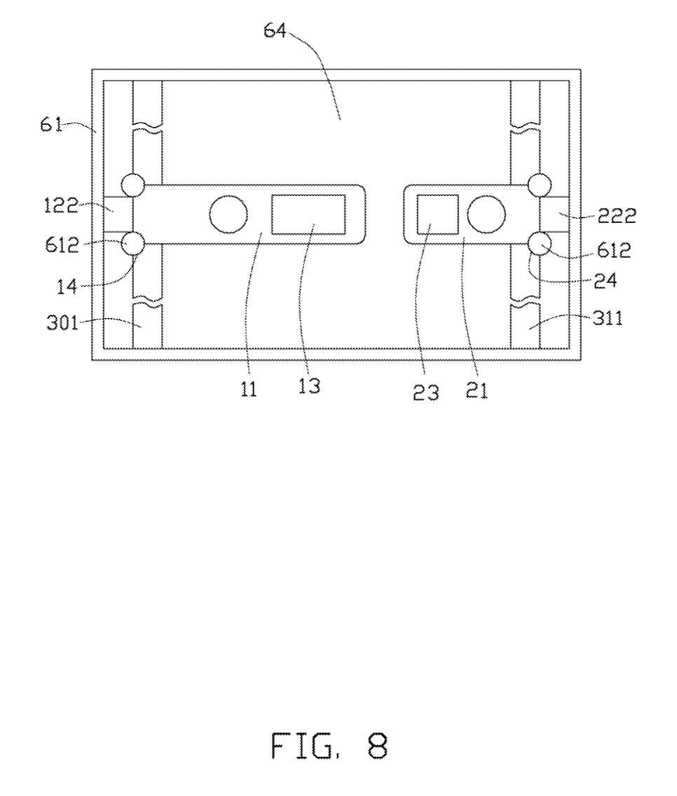

Referring to FIGS. 7-8, the molded bodies 70 are formed in a mold 60 by injection molding. The mold 60 includes a male mold 61, and a female mold 62 engaged with the male mold 61. The male and female molds 61, 62 cooperatively define a cavity 63 therein. The lead frame 50 is received in the cavity 63 of the mold 60.

The mold 60 includes a plurality of stems 612 extending from the male mold 61 thereof to correspond to the first and second recesses 14, 24. The stems 612 are engagingly received into the corresponding first and second recesses 14, 24 during the injection molding process (see FIG. 8). In the present embodiment, the first and second recesses 14, 24 are semi-cylindrical. The stems 612 are cylindrical and have an outer diameter fittingly mated with that of the first and second recesses 14, 24.

A length of the stem 612 is substantially the same as heights of the extension portions 122, 222 of the first and second extension electrode 12, 22 and thicknesses of the first and second tie bars 30, 31. Tops of the first and second extension electrodes 12, 22 of each pair of the first and second electrodes 10, 20 are totally covered by the male mold 61. Tops of the first and second main bodies 11, 21 of each pair of the first and second electrodes 10, 20 are partially covered by the male mold 61. Each first tie bar 30, the first extension electrodes 11 connected by the first tie bar 30, a second tie bar 31 adjacent to the first tie bar 30, the second extension electrodes 21 connected by the second tie bar 31, the stems 612 engaged in the first and second recesses 14, 24, and two opposite sides of the lead frame 50 cooperatively define an enclosed area 64.

The molded body 70 is made of a material selected from a group consisting of polyphthalamide (PPA) resin, epoxy molding compound, and silicone molding compound. The melted molding materials are injected into the enclosed areas 64 of the cavity 63 through channels 611 formed in the male mold 61, respectively. The molding materials flow around the first and second supporting branches 13, 23 of the each pair of the first and second electrodes 10, 20, and flows through the first and second through holes 113, 213, thereby forming the reflecting cups 71. The plurality of reflecting cups 71 disposed in a column are integrally formed as a single piece, i.e., the molded body 70. Each reflecting cup 71 defines a receiving cavity 72 located above the corresponding pair of the first and second electrodes 10, 20.

In step S103, a plurality of LED dies 80 are disposed in the corresponding receiving cavities 72. Each LED die 80 is electrically connected to the corresponding pair of the first and second electrodes 10, 20 exposed at a bottom of the corresponding receiving cavity 72 via gold wires 81, 82 (see FIG. 14).

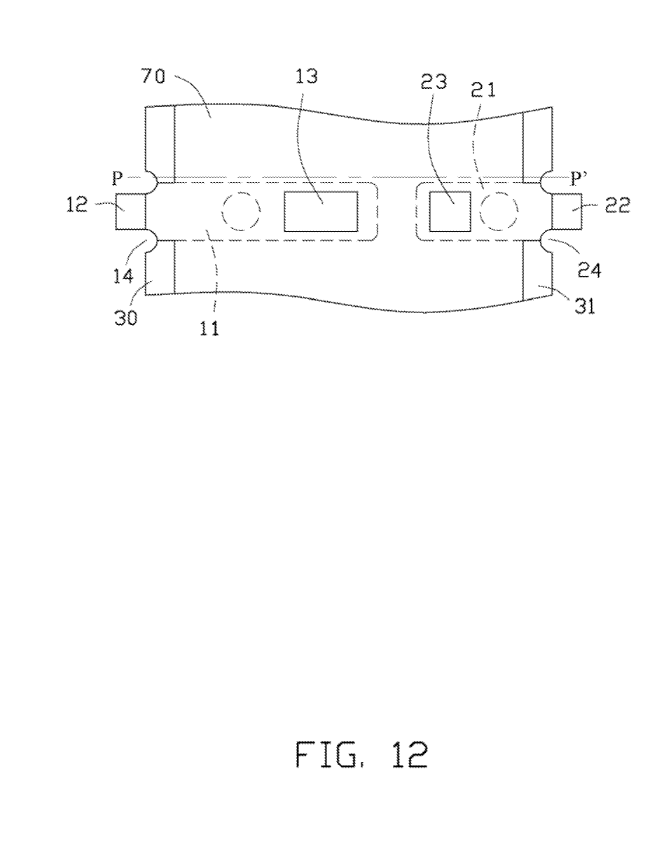

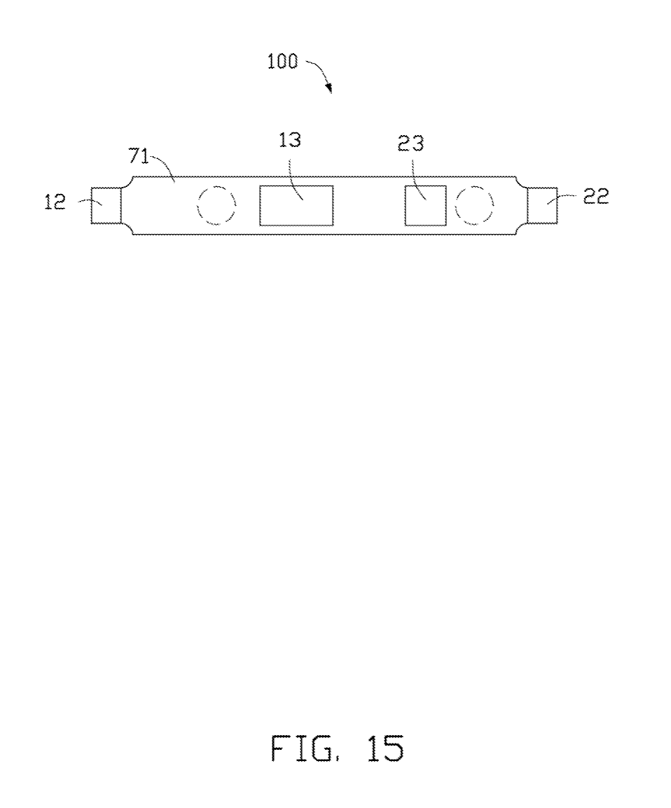

In step S104, the lead frame 50, the first and second tie bars 30, 31, and the molded bodies 70 are cut along connecting lines PP′ (see FIG. 12) of the adjacent first and second recesses 14, 24. After cutting along a line perpendicular to the connecting lines PP′ to separate adjacent first and second electrodes 10, 20, a plurality of individual LED packages 100 as shown in FIG. 15 are obtained. In the present embodiment, the lead frame 50, the first and second tie bars 30, 31, and the molded bodies 70 are separated into individual elements by machining cut along connecting lines PP′ in a lateral direction and then along a longitudinal direction perpendicular to the lateral direction.

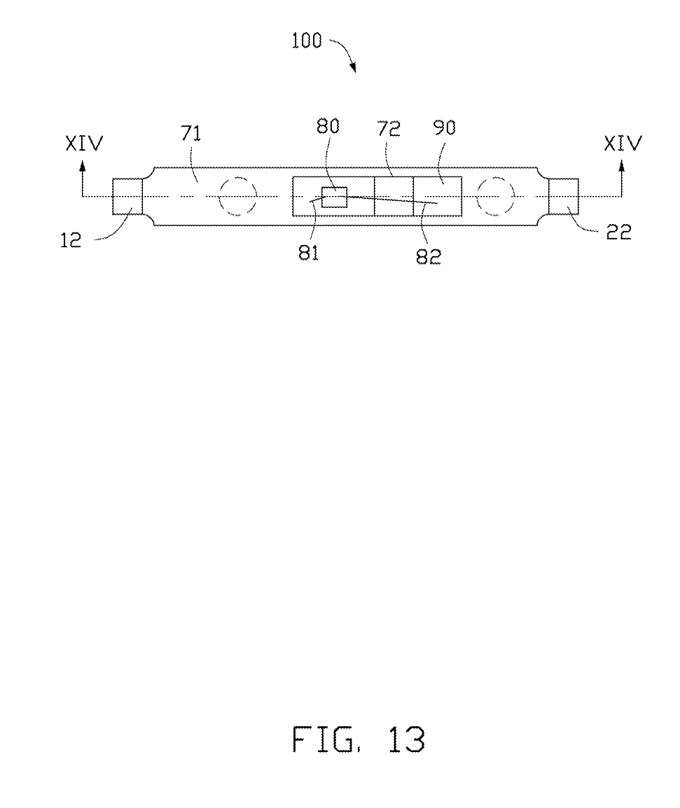

Referring to FIGS. 13-15, the LED package 100 includes a pair of the first and second electrodes 10, 20, a reflecting cup 71 surrounding the pair of the first and second electrodes 10, 20, and an LED die 80 disposed in the receiving cavity 72 of the reflecting cup 71 and electrically connected to the pair of the first and second electrodes 10, 20. The first and second extension electrodes 12, 22 are exposed out of a periphery of the corresponding reflecting cup 71. The first and second supporting branches 13, 23 are exposed at a bottom of the corresponding reflecting cup 71.

Alternatively, the LED dies 80 can be disposed in the corresponding receiving cavities 72 of the reflecting cups 71 after the lead frame 50, the first and second tie bars 30, 31, and the molded bodies 70 are cut along connecting liens PP′ of the adjacent first and second recesses 14, 24.

It is to be understood that the method further includes a step of forming an encapsulant layer 90 (see FIG. 14) in the receiving cavity 72 of the each reflecting cup 71 to encapsulate the LED die 80 after the LED dies 80 are disposed in the corresponding receiving cavities 72. The encapsulant layer 90 contains phosphor particles (not labeled) therein to scatter and transfer a wavelength of light emitted from the LED die 80.

In the present disclosure, the first and second electrodes 10, 20 includes the first and second supporting branches 13, 23 completely embedded into the corresponding reflecting cup 71, thus the bonding strength between the pair of the first and second electrodes 10, 20 and the reflecting cup 71 is enhanced. Furthermore, a plurality of first recess 14 is preformed at joints where each first electrode 10 meets the corresponding first tie bar 30, and a plurality of second recess 24 is preformed at joints where each second electrode 20 meets the corresponding second tie bar 31, which can facilitate cutting without producing burs on the cut surface of the first and second tie bars 30, 31. In addition, the LED package 100 can be electrically connected to external power source (not shown) through bottoms of the first and second supporting branches 13, 23 or the first and second extension electrodes 12, 22, thus the LED package 100 can be used as a top-view type light source or a side-view type light source according to actual requirements.

In use, heat generated from the LED die 80 is mainly conducted to the first and second electrodes 10, 20, a part of the heat absorbed by the first and second electrodes 10, 20 is dissipated to the ambient environment through bottoms of the first and second supporting branches 13, 23, and a part of the heat absorbed by the first and second electrodes 10, 20 is dissipated to the ambient environment through the first and second extension electrodes 12, 22. Thus, the LED package 100 can have a high heat-dissipating efficiency.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A method for manufacturing the LED package comprising:
providing a lead frame, the lead frame comprising a plurality of pairs of electrodes arranged in a matrix, each pair of electrodes comprising a first electrode and a second electrode adjacent to the first electrode, the first electrodes being arranged in a plurality of columns, and the second electrodes being arranged in a plurality of columns, wherein each first electrode comprises an elongated first main body, a first extension electrode protruding laterally from one end of the first main body, and a first supporting branch protruding downwardly from a bottom of the first main body, and each second electrode comprises an elongated second main body, a second extension electrode protruding laterally from one end of the second main body, and a second supporting branch protruding downwardly from a bottom of the second main body, the first electrodes arranged in the same column being linearly connected together by a first tie bar, the second electrodes arranged in the same column being linearly connected together by a second tie bar, a plurality of first recesses being defined at joints where each first electrode meets the corresponding first tie bar, a plurality of second recesses being defined at joints where each second electrode meets the corresponding second tie bar;
forming a plurality of molded bodies to correspond to the pairs of the first and second electrodes, each molded body surrounding and covering a plurality of pairs of the first and second electrodes disposed in two adjacent columns, and each molded body forming a plurality of reflecting cups, each reflecting cup defining a receiving cavity therein and being located over a corresponding pair of the first and second electrodes, wherein the first and second extension electrodes, together with the first and second tie bars, are exposed from an outer periphery of the corresponding molded body, and bottoms of the first and second supporting branches are exposed at a bottom of the corresponding molded body;
disposing a plurality of LED dies in the corresponding receiving cavities, each LED die being electrically connected to the corresponding pair of first and second electrodes exposed at a bottom of the corresponding receiving cavity; and
cutting the molded bodies and the first and second tie bars and the lead frame along connecting lines of the adjacent first and second recesses in a first direction and then along a second direction perpendicular to the first direction to obtain a plurality of individual LED packages, each LED package comprising a pair of the first and second electrodes, a reflecting cup surrounding the pair of the first and second electrodes, and an LED die disposed in a receiving cavity of the reflecting cup.

2. The method for manufacturing an LED package of claim 1, wherein the first extension electrode of each pair of the first and second electrodes is located at the end of the first main body away from the second electrode, and the second extension electrode of each pair of the first and second electrodes is located at the end of the second main body away from the first electrode.

3. The method for manufacturing an LED package of claim 2, wherein the first and second extension electrodes each have an inverted L-shaped configuration.

4. The method for manufacturing an LED package of claim 3, wherein each first extension electrode comprises a first connecting portion extending horizontally outwardly from the first main body and a first extension portion extending downwardly from the distal end of the first connecting portion, and each second extension electrode comprises a second connecting portion extending horizontally outward from the second main body and a second extension portion extending downwardly from the distal end of the second connecting portion.

5. The method for manufacturing an LED package of claim 4, wherein tops of the first and second extension electrodes are respectively coplanar with tops of the first and second main bodies, and bottoms of the first and second extension electrode are respectively coplanar with the bottoms of the first and second supporting branches.

6. The method for manufacturing an LED package of claim 4, wherein widths of the first and second extension electrodes are smaller than that of the corresponding first and second main bodies.

7. The method for manufacturing an LED package of claim 4, wherein the first tie bar comprises a plurality of spaced first connecting sections, and the second tie bar comprises a plurality of spaced second connecting sections, each first connecting section extends between every two adjacent first electrodes disposed in the same column, each second connecting section extends between every two adjacent second electrodes disposed in the same column, the first connecting section is adjacent to the first extension electrode of the first electrode, and the second connecting section is adjacent to the second extension electrode of the second electrode.

8. The method for manufacturing an LED package of claim 7, wherein the first extension electrode has two first cutouts at opposite sides of thereof, and the second extension electrode has two second cutouts at opposite sides thereof.

9. The method for manufacturing an LED package of claim 8, wherein the two first cutouts are respectively located at opposite sides of the first connecting portion of the first extension electrode, and the two second cutouts are respectively located at opposite sides of the second connecting portion of the second extension electrode.

10. The method for manufacturing an LED package of claim 9, wherein the first connecting section has two third cutouts formed at opposite ends thereof, and the second connecting section has two fourth cutouts formed at opposite ends thereof, the first cutout of the first extension electrode and the adjacent third cutout of the first connecting section cooperatively defines the first recess, and the second cutout of the second extension electrode and the adjacent fourth cutout of the second connecting section cooperatively defines the second recess.

11. The method for manufacturing an LED package of claim 1, wherein tops of the first and second tie bars are respectively coplanar with tops of the first and second main bodies, and bottoms of the first and second tie bars are respectively coplanar with the bottoms of the first and second supporting branches.

12. The method for manufacturing an LED package of claim 1, wherein the first and second supporting branches are square cylindrical, a width of the first supporting branch is smaller than that of the first main body, and a width of the second supporting branch is smaller than that of the second main body.

13. The method for manufacturing an LED package of claim 12, wherein the first supporting branch of the pair of first and second electrodes is near to the right end of the first electrode and adjacent to the second electrode, and the second supporting branch of the pair of first and second electrodes is near to the left end of the second electrode and adjacent to the first electrode.

14. The method for manufacturing an LED package of claim 13, wherein each first electrode further comprises a first through hole extending through the first main body thereof, and each second electrode further comprises a second through hole extending through the second main body thereof, the first and second through holes being filled by molding material after the step of forming the molded bodies.

15. The method for manufacturing an LED package of claim 1, further comprising a step of forming an encapsulant layer in the receiving cavity of each reflecting cup to encapsulate the LED die therein after the LED dies being received in the corresponding receiving cavities.

16. The method for manufacturing an LED package of claim 1, wherein the molded body is formed in a mold by injection molding, the mold comprising a male mold and a female mold engaged with the male mold, the male mold and the female mold cooperatively defining a cavity to receive the lead frame therein.

17. The method for manufacturing an LED package of claim 16, wherein the molded body is made of a material selected from a group consisting of polyphthalamide resin, epoxy molding compound, and silicone molding compound.

18. The method for manufacturing an LED package of claim 16, wherein the mold comprises a plurality of stems extending from the male mold thereof to correspond to the first and second recesses, the stems being engagingly received into the corresponding first or second recess during the injection molding process.

19. The method for manufacturing an LED package of claim 18, wherein a length of the stem is substantially same as heights of the first and second extension electrodes, and thicknesses of the first and second tie bars.

20. The method for manufacturing an LED package of claim 16, wherein tops of the first and second electrodes are partially covered by the male mold, and the molding material flows in a plurality of enclosed areas, each enclosed area being cooperatively defined by a first tie bar, the first extension electrodes connected by the first tie bar, a second tie bar adjacent to the first tie bar, the second extension electrodes connected by the second tie bar, the stems engaged into the first and second recesses, and two opposite sides of the lead frame.
